(19) United States
(12) Patent Application Publication
(10) Pub. No.: US 2013/0160846 A1
(43) Pub. Date: Jun. 27, 2013

(54) PHOTOVOLTAIC DEVICE

(71) Applicant: SANYO ELECTRIC CO., LTD., Osaka (JP)

(72) Inventor: Shigeo YATA, Ogaki-shi (JP)

(73) Assignee: SANYO ELECTRIC CO., LTD., Osaka (JP)

(21) Appl. No.: 13/765,456

(22) Filed: Feb. 12, 2013

Related U.S. Application Data
(63) Continuation of application No. PCT/JP2012/061173, filed on Apr. 26, 2012.

(30) Foreign Application Priority Data
May 13, 2011 (JP) 2011-107761

(51) Int. Cl. H01L 31/0352

(52) U.S. Cl. CPC H01L 31/035245
USPC 136/256

(57) ABSTRACT

A photovoltaic device is provided which comprises: a transparent substrate; a front-side electrode layer formed over the substrate and comprising a transparent conductive film; a photovoltaic unit formed over the front-side electrode layer; and a backside electrode layer formed over the photovoltaic unit and comprising a transparent conductive film. The backside electrode layer has a structure in which a contact region joined with the photovoltaic unit, a light scattering region having a lower dopant concentration than the contact region, and a conductive region having a higher density than the light scattering region, are layered.

### CROSS-REFERENCE TO RELATED APPLICATIONS

The present application is a continuation application of International Application No. PCT/JP2012/061173, filed Apr. 26, 2012, the entire contents of which are incorporated herein by reference and priority to which is hereby claimed. The PCT/JP2012/061173 application claimed the benefit of the dates of earlier filed Japanese Patent Application No. 2011-107761 filed May 13, 2011, the entire contents of which are incorporated herein by reference, and priority to which is hereby claimed.

### BACKGROUND

1. Technical Field

The present invention relates to a photovoltaic device.

2. Related Art

As a power generation system which uses solar light, photovoltaic devices are used in which semiconductor thin films such as amorphous semiconductor thin films or microcrystalline semiconductor thin films are layered.

FIG. 8 is a schematic cross-sectional diagram of a basic structure of a photovoltaic device 100. The photovoltaic device 100 is formed by layering, over a substrate 10 such as glass, a front-side electrode layer 12, a photovoltaic unit 14, and a backside electrode layer 16. When a transparent substrate is employed as the substrate 10 and the light is allowed to enter from the side of the substrate 10, the front-side electrode layer 12 is formed with a transparent conductive film (TCO). In addition, the backside electrode layer 16 is in many cases formed as a layered structure of a transparent conductive film and a metal film, but alternatively, a structure may be employed in which a reflective sealing member is placed over the transparent conductive film and the metal film is not layered. The transparent conductive film which is employed for the front-side electrode layer 12 and the backside electrode layer 16 is generally formed through MOCVD or sputtering (refer to, for example, JP 2008-277387 A)

A structure is disclosed having a first transparent electrode layer with a surface unevenness and a low-resistance, second transparent electrode layer including zinc oxide doped with impurities at a higher concentration than the first transparent electrode layer. In this case, preferably, the second transparent electrode layer is formed with a deposition rate of half or less of a deposition rate of the first transparent electrode layer.

When a transparent conductive film is employed for the front-side electrode layer 12 or the backside electrode layer 16, in order to improve the conversion efficiency of the photovoltaic device, a film having a low contact resistance with the photovoltaic unit, a high electrical conductivity, a low absorption of light, and a high light scattering effect is desired.

In addition, the substrate 10 may be warped by mechanical stress between the front-side electrode layer 12 or the backside electrode layer 16 which is a transparent conductive film and the photovoltaic unit 14, and the warping may cause a problem such as peeling off of the layered film. Therefore, it is desired to inhibit such warping and to consequently improve the reliability of the photovoltaic device.

### SUMMARY

According to one aspect of the present invention, there is provided a photovoltaic device comprising a transparent substrate, a front-side electrode layer formed over the substrate and comprising a transparent conductive film, a photovoltaic unit formed over the front-side electrode layer, and a backside electrode layer formed over the photovoltaic unit and comprising a transparent conductive film, wherein the backside electrode layer has a structure in which a first contact region joined with the photovoltaic unit, a first light scattering region having a lower dopant concentration than the first contact region, and a first conductive region having a higher density than the first light scattering region, are layered.

### BRIEF DESCRIPTION OF THE DRAWINGS

FIG. 1 is a cross-sectional diagram showing a structure of a photovoltaic device according to a first preferred embodiment of the present invention.

FIG. 2 is a diagram showing a structure of a backside electrode layer in the first preferred embodiment of the present invention.

FIG. 3 is a diagram showing a total transmittance of a contact region and a light scattering region in the first preferred embodiment of the present invention.

FIG. 4 is a diagram showing a total transmittance of the light scattering region and a conductive region in the first preferred embodiment of the present invention.

FIG. 5 is a diagram showing a structure of a transparent electrode layer in the first preferred embodiment of the present invention.

FIG. 6 is a cross-sectional diagram showing a structure of a photovoltaic device according to a second preferred embodiment of the present invention.

FIG. 7 is a cross-sectional diagram showing a structure of a photovoltaic device according to a third preferred embodiment of the present invention.

FIG. 8 is a cross-sectional diagram showing a structure of a photovoltaic device of related art.

### DETAILED DESCRIPTION

### First Preferred Embodiment

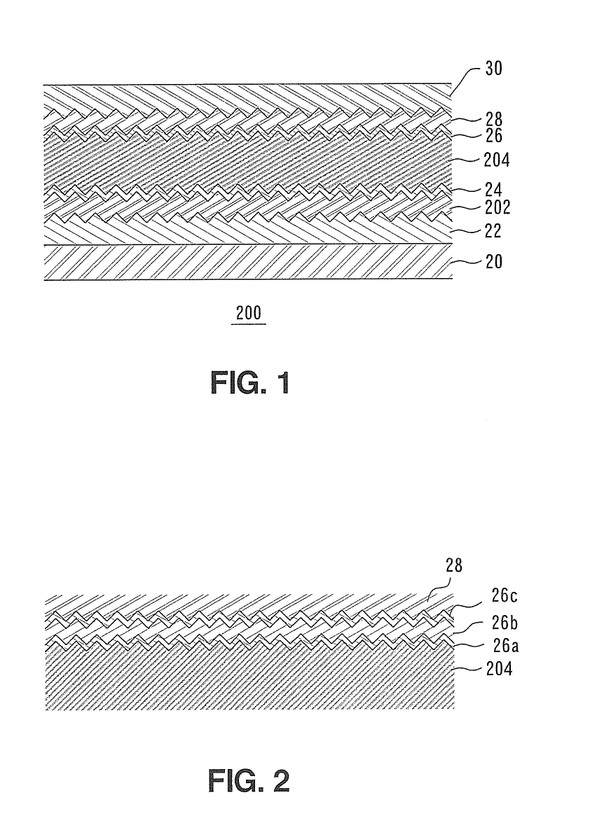

As shown in FIG. 1, a photovoltaic device 200 according to a first preferred embodiment of the present invention has a structure in which, with a substrate 20 as a light incidence side, a front-side electrode layer 22, an amorphous silicon photovoltaic unit (a-Si unit) 202 serving as a top cell and having a wide band gap, an intermediate layer 24, a microcrystalline silicon photovoltaic unit (μc-Si unit) 204 serving as a bottom cell and having a narrower band gap than the a-Si unit 202, a backside electrode layer 26, a filler 28, and a back sheet 30, are layered from the light incidence side.

In the present embodiment, as the photovoltaic unit which is a power generation layer, a tandem type photovoltaic device in which the a-Si unit 202 and the μc-Si unit 204 are layered is exemplified, but application of the present invention is not limited to such a configuration, and the present invention may alternatively be applied to, for example, a single-type photovoltaic device or a photovoltaic device with a larger number of layers.

For the substrate 20, a material which transmits light in at least the visible light wavelength region, such as a glass substrate and a plastic substrate, may be employed.

The front-side electrode layer 22 is formed over the substrate 20. For the front-side electrode layer 22, preferably, one or a combination of a plurality of transparent conductive oxides (TCO) are employed in which tin oxide (SnO₂), zinc oxide (ZnO), indium tin oxide (ITO), or the like is doped with tin (Sn), antimony (Sb), fluorine (F), aluminum (Al) or the like. In particular, zinc oxide (ZnO) is preferable because zinc oxide has a high light transmittance, a low resistivity, and a high plasma-resisting characteristic. Moreover, it is also preferable to forma texture structure in the front-side electrode layer 22.

When a structure in which a plurality of cells are connected in series is employed for the photovoltaic device 200, the front-side electrode layer 22 is patterned in a strip shape. For example, a YAG laser having a wavelength of 1064 nm, an energy density of 13 J/cm², and a pulse frequency of 3 kHz may be used to pattern the front-side electrode layer 22 in the strip shape.

Silicon-based thin films including a p-type layer, an i-type layer, and an n-type layer are sequentially layered over the front-side electrode layer 22, to form the a-Si unit 202. The a-Si unit 202 may be formed through plasma chemical vapor deposition (CVD) in which mixture gas of silicon-containing gas such as silane (SiH₄) disilane (Si₂H₆) and dichlorsilane (SiH₂Cl₂) carbon-containing gas such as methane (CH₄), p-type dopant-containing gas such as diborane (B₂H₆), n-type dopant-containing gas such as phosphine (PH₃), and dilution gas such as hydrogen (H₂) is formed into plasma and the films are formed.

For the plasma CVD, for example, an RF plasma CVD of 13.56 MHz is preferably employed. The RF plasma CVD may be of a parallel plate type. On a side of the parallel plate-type electrodes in which the substrate 20 is not placed, a gas shower hole for supplying the mixture gas of the materials may be provided. An input power density of plasma is preferably set to greater than or equal to 5 mW/cm² and less than or equal to 300 mW/cm².

As the p-type layer, a single-layer structure or a layered structure of an amorphous silicon layer, a microcrystalline silicon thin film, and a microcrystalline silicon carbide thin film, is employed which is doped with a p-type dopant (such as boron) and which has a thickness of greater than or equal to 5 nm and less than or equal to 50 nm. A film characteristic of the p-type layer can be changed by adjusting the mixture ratio of the silicon-containing gas, the p-type dopant-containing gas, and dilution gas, a pressure, and a plasma generating high-frequency power. For the i-type layer, an amorphous silicon film is employed which is formed over the p-type layer, which is not doped with any dopant, and which has a thickness of greater than or equal to 50 nm and less than or equal to 500 nm. A film characteristic of the i-type layer can be changed by adjusting the mixture ratio of the silicon-containing gas and the dilution gas, a pressure, and a plasma generating high-frequency power. The i-type layer forms a power generation layer of the a-Si unit 202. For the n-type layer, an n-type microcrystalline silicon layer (n-type μc-Si:H) may be employed which is formed over the i-type layer, which is doped with an n-type dopant (such as phosphor), and which has a thickness of greater than or equal to 10 nm and less than or equal to 100 nm. A film characteristic of the n-type layer can be changed by adjusting the mixture ratio of the silicon-containing gas, the carbon-containing gas, the n-type dopant-containing gas, and the dilution gas, a pressure, and a plasma generating high-frequency power. The films of the a-Si unit 202 may be formed, for example, with the film formation conditions shown in TABLE 1, although the conditions are not limited to these conditions.

TABLE 1

| | | SUBSTRATE | GAS FLOW | REACTION | RF | |
|---|---|---|---|---|---|---|
| | | TEMPERATURE | RATE | PRESSURE | POWER | THICKNESS |
| | LAYER | (° C.) | (sccm) | (Pa) | (W) | (nm) |
| a-Si | p-TYPE LAYER | 180 | SiH₄: 300 | 106 | 10 | 15 |
| UNIT | | | CH₄: 300 | | | |
| 202 | | | H₂: 2000 | | | |
| | | | B₂H₆: 3 | | | |
| | i-TYPE LAYER | 180 | SiH₄: 300 | 106 | 20 | 250 |
| | | | H₂: 2000 | | | |
| | n-TYPE LAYER | 180 | SiH₄: 300 | 133 | 20 | 30 |
| | | | H₂: 2000 | | | |
| | | | PH₃: 5 | | | |

The intermediate layer 24 is formed over the a-Si unit 202. For the intermediate layer 24, a transparent conductive oxide (TCO) such as zinc oxide (ZnO) and silicon oxide (SiOx) is preferably employed. In particular, zinc oxide (ZnO) or silicon oxide (SiOx) doped with magnesium (Mg) is preferably employed. The intermediate layer 24 may be formed, for example, through sputtering. A film thickness of the intermediate layer 24 is preferably set in a range of greater than or equal to 10 nm and less than or equal to 200 nm. Alternatively, the intermediate layer 24 may be omitted.

The μc-Si unit 204 in which a p-type layer, an i-type layer, and an n-type layer are sequentially layered is formed over the intermediate layer 24. The μc-Si unit 204 can be formed through plasma CVD in which mixture gas of silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is formed into plasma and the films are formed.

For the plasma CVD, similar to the a-Si unit 202, for example, RF plasma CVD of 13.56 MHz may be preferably employed. The RF plasma CVD may be of a parallel plate type. On a side of the electrodes of the parallel plate type in which the substrate 20 is not placed, a gas shower hole for supplying the mixture gas of the materials may be provided. An input power density of the plasma is preferably set to greater than or equal to 5 mW/cm² and less than or equal to 300 mW/cm².

For the p-type layer, a microcrystalline silicon layer (μc-Si:H) is employed which has a thickness of greater than or equal to 5 nm and less than or equal to 50 nm and which is doped with a p-type dopant (such as boron). A film characteristic of the p-type layer can be changed by adjusting a mixture ratio of the silicon-containing gas, the p-type dopant-containing gas, and the dilution gas, a pressure, and a plasma generating high-frequency power.

For the i-type layer, a microcrystalline silicon layer (μc-Si:H) is employed which is formed over the p-type layer, which has a thickness of greater than or equal to 0.5 μm and less than or equal to 5 μm, and which is not doped with any dopant. A film characteristic of the i-type layer can be changed by adjusting the mixture ratio of the silicon-containing gas and the dilution gas, a pressure, and a plasma generating high-frequency power.

For the n-type layer, a microcrystalline silicon layer (n-type μc-Si:H) is layered which has a thickness of greater than or equal to 5 nm and less than or equal to 50 nm and which is doped with an n-type dopant (such as phosphor). A film characteristic of the n-type layer can be changed by adjusting the mixture ratio of the silicon-containing gas, the n-type dopant-containing gas, and the dilution gas, a pressure, and a plasma generating high-frequency power. The films of the μc-Si unit 204 may be formed, for example, under the film formation conditions shown in TABLE 2, although the film formation conditions are not limited to these conditions.

TABLE 2

| | | SUBSTRATE | GAS FLOW | REACTION | RF | |
|---|---|---|---|---|---|---|
| | | TEMPERATURE | RATE | PRESSURE | POWER | THICKNESS |
| | LAYER | (° C.) | (sccm) | (Pa) | (W) | (nm) |
| μc-Si | p-TYPE LAYER | 180 | SiH₄: 10 | 106 | 10 | 30 |
| UNIT | | | H₂: 2000 | | | |
| 204 | | | B₂H₆: 3 | | | |
| | i-TYPE LAYER | 180 | SiH₄: 100 | 133 | 20 | 2000 |
| | | | H₂: 2000 | | | |
| | n-TYPE LAYER | 180 | SiH₄: 10 | 133 | 20 | 20 |
| | | | H₂: 2000 | | | |
| | | | PH₃: 5 | | | |

When a plurality of cells are connected in series, the a-Si unit 202, the intermediate layer 24, and the μc-Si unit 204 are patterned in a strip shape. A YAG laser is irradiated at a position beside the patterning position of the front-side electrode layer 22 by 50 nm to form a slit, and the a-Si unit 202 and the μc-Si unit 204 are patterned in the strip shape. For example, a YAG laser having an energy density of 0.7 J/cm² and a pulse frequency of 3 KHz may be preferably employed.

The backside electrode layer 26 is formed over the μc-Si unit 204. In the present embodiment, as shown in FIG. 2, the backside electrode layer 26 has a structure in which a contact region 26a, a light scattering region 26b, and a conductive region 26c are sequentially layered from the side of the μc-Si unit 204.

The contact region 26a is a region provided for achieving a superior electrical contact with the photovoltaic unit which is the μc-Si unit 204. The contact region 26a is formed to have a higher dopant concentration than the light scattering region 26b to be described later. The light scattering region 26b is a region provided to scatter the incident light and to achieve a light confinement effect for the photovoltaic device 200.

The contact region 26a and the light scattering region 26b may be formed through chemical vapor deposition (CVD). For example, when zinc oxide (ZnO) is to be employed for the contact region 26a and the light scattering region 26b, the regions can be formed through low-pressure metal organic chemical vapor deposition (LP-MOCVD) using material gas in which diethyl zinc (DEZ: (C₂H₅)₂Zn), water, and doping gas are mixed. Alternatively, for the material gas of zinc, dimethyl zinc may be employed. As the doping gas, diborane (B₂H₆) may be employed. Under conditions of a substrate temperature of greater than or equal to 150° C. and a pressure of greater than or equal to 0.1 mbar and less than or equal to 10 mbar, while the DEZ and the water are supplied after being vaporized through heating, bubbling, or spraying, the doping gas is introduced.

The contact region 26a is formed in a state where the doping gas is increased compared to the light scattering region 26b. For example, the contact region 26a and the light scattering region 26b may be formed under the film formation conditions shown in TABLE 3.

TABLE 3

| | TEMPERATURE | PRESSURE | GAS FLOW RATE |
|---|---|---|---|
| | (° C.) | (mbar) | (sccm) |
| CONTACT | 180 | 0.5 | (C₂H₅)₂Zn: 650 |
| REGION 26a | | | H₂O: 750 |
| | | | 1%B₂H₆/H₂: 300 |
| | | | H₂: 100 |
| LIGHT | 180 | 0.5 | (C₂H₅)₂Zn: 650 |
| SCATTERING | | | H₂O: 750 |
| REGION 26b | | | 1%B₂H₆/H₂: 125 |
| | | | H₂: 100 |

Here, in order to avoid, during the film formation, the phenomenon that the crystallinity of the contact region 26a forming the underlying layer is continued and the grain size of the light scattering region 26b becomes small, the films are preferably formed so that the dopant concentration near the boundary between the contact region 26a and the light scattering region 26b is steep. More specifically, it is preferable that the thickness of a transition region where the dopant concentration changes is set smaller than 1/20th of a total thickness of the contact region 26a and the light scattering region 26b.

The conductive region 26c is an electrical conductive layer having a higher density than the light scattering region 26b, a high electrical conductivity, and a low light absorption. The light scattering region 26b is a light scattering layer having a lower density than the conductive region 26c and in which a texture structure is formed. By employing such a layered structure for the backside electrode layer 26, a transparent electrode can be obtained having a high electrical conductivity, a low light absorption, and a high light scattering effect.

The conductive region 26c can be formed through sputtering. In the sputtering, a target including an element forming a material of the conductive region 26c is placed opposing the substrate 20 placed in a vacuum chamber, and the target is sputtered by sputtering gas such as argon which is formed into plasma, to deposit the material over the μc-Si unit 204 and form the conductive region 26c. For example, the conductive region 26c is formed through sputtering under a high-density magnetic field. With such a configuration, the conductive region 26c which forms the electrical conductive layer becomes a denser layer than the light scattering region 26b which forms the light scattering layer, and consequently, a higher electrical conductivity and a lower light absorption than the light scattering region 26b can be achieved.

For example, the conductive region 26c is preferably formed through magnetron sputtering as shown in TABLE 4. The conductive region 26c is formed by placing the substrate 20 and a target within a vacuum chamber opposing each other with a surface distance of 50 mm, introducing argon gas into the vacuum chamber with a flow rate of 100 sccm and a pressure of 0.7 Pa with a substrate temperature of 150° C., and forming a plasma with a power of 500 W. In this case, the magnetic field is set at 1000 G.

TABLE 4

| | | | | | GAS | T-S | MAGNETIC | |
|---|---|---|---|---|---|---|---|---|
| | MANUFACTURING | TEMPERATURE | PRESSURE | POWER | FLOW RATE | DISTANCE | FIELD | |
| | METHOD | (° C.) | (Pa) | (W) | (sccm) | (mm) | (G) | TARGET |
| CONDUCTIVE | MAGNETRON | 150 | 0.7 | 500 | Ar: 100 | 50 | 1000 | 2 wt % Ga₂O₃ |
| LAYER 26c | SPUTTERING | | | (DC) | | | | DOPED ZnO |

When a structure in which a plurality of cells are connected in series is employed for the photovoltaic device 200, the backside electrode layer 26 is patterned into a strip shape. A YAG laser is irradiated at a position beside the patterning positions of the a-Si unit 202 and the μc-Si unit 204 by 50 μm to form a slit, and to pattern the backside electrode layer 26 in the strip shape. A YAG laser having an energy density of 0.7 J/cm² and a pulse frequency of 4 kHZ may be preferably employed.

Further, a surface of the backside electrode layer 26 is covered by the filler 28 and with a back sheet 30. For the filler 28 and the back sheet 30, a resin material such as EVA and polyimide may be employed. Alternatively, for the back sheet 30, a transparent substrate such as a glass substrate and a plastic substrate, similar to the substrate 20, may be employed. With such a configuration, intrusion of moisture or the like into the power generation layer of the photovoltaic device 200 can be prevented.

Next, an advantage of employing the layered structure of the contact region 26a, the light scattering region 26b, and the conductive region 26c for the backside electrode layer 26 will be described.

For structures in which the contact region 26a and the light scattering region 26b were formed over the glass substrate under the film formation conditions of TABLE 3, with a total thickness of 2.0 μm, and ratios of the film thicknesses being 1:1 and 1:3, a haze rate and a total transmittance were measured. As a Comparative Example, a structure was created in which the light scattering region 26b was not formed and only the contact region 26a was formed to a thickness of 2.0 μm.

Here, the haze rate was used as an evaluation index of unevenness of the transparent electrode film. The haze rate is determined by (diffused transmittance/total light transmittance)×100 [%] (JIS K7136). As a simple evaluation method of the haze rate, generally, measurement using a haze meter with a D65 light source or a C light source is employed.

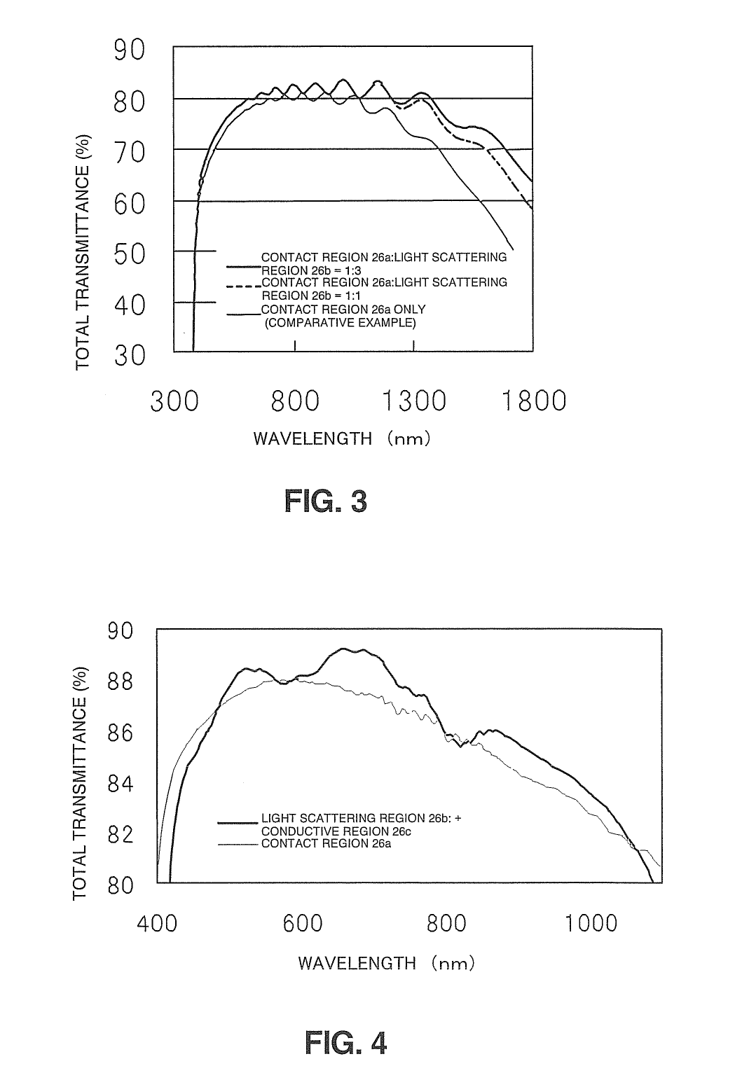

As a result of the measurement, it was found that the haze rate was almost constant at any thickness ratio, and there was no difference from the Comparative Example. As shown in FIG. 3, the total transmittance was increased as the thickness of the light scattering region 26b was increased. It can be deduced that this is caused by the absorption of the light being smaller for the light scattering region 26b having a lower dopant concentration than the contact region 26a. In addition, with the lower dopant concentration, a grain size of the light scattering region 26b becomes larger than a grain size of the contact region 26a, and consequently, the light scattering effect in the light scattering region 26b is larger than the contact region 26a. Therefore, the light confinement effect for the photovoltaic device 200 is also improved.

On the other hand, the contact region 26b has a higher dopant concentration and a lower resistivity than the light scattering region 26b. Therefore, the contact resistance with the μc-Si unit 204 which is the photovoltaic region can be reduced and a superior contact characteristic can be provided.

The fact that the backside electrode layer 26 includes a layered structure of the contact region 26a and the light scattering region 26b can be confirmed by measuring the dopant using secondary ion mass spectroscopy (SIMS) That is, because the contact region 26a has a higher dopant concentration than the light scattering region 26b, if there is a point where the dopant concentration discontinuously increases in the dopant concentration change in the thickness direction from the side of the μc-Si unit 204, this point is the boundary between the contact region 26a and the light scattering region 26b, and it can be understood that the backside electrode layer 26 includes the layered structure of the contact region 26a and the light scattering region 26b.

TABLE 5 shows a sheet resistance and the haze rate when the light scattering region 26b and the conductive region 26c are layered over the glass substrate. The light scattering region 26b was formed with a thickness of 1500 nm under the conditions shown in TABLE 3, and the conductive region 26c was formed with a thickness of 400 nm under the conditions shown in TABLE 4. In addition, a structure in which the contact region 26a was formed with a thickness of 1500 nm over the glass substrate under the conditions shown in TABLE 3 was set as a Comparative Example. The layered structure of the conductive region 26c and the light scattering region 26b had a lower sheet resistance than the Comparative Example. In addition, the layered structure of the conductive region 26c and the light scattering region 26b had a higher haze rate, that is, superior optical effect such as the light confinement, than the Comparative Example.

TABLE 5

| | SHEET REGISTANCE | HAZE RATE |
|---|---|---|
| | (Ω/sq) | (%) |
| LIGHT SCATTERING | 7.7 | 22.1 |
| REGION 26b + | | |
| CONDUCTIVE REGION 26c | | |
| CONTACT | 9.1 | 21.6 |
| REGION 26a | | |

FIG. 4 shows a wavelength dependency of the total transmittance for a case where the light scattering region 26b and the conductive region 26c are layered over the glass substrate and for a case where the contact region 26a is formed with a thickness of 1500 nm under the conditions shown in TABLE 3. As shown in FIG. 4, the layered structure of the conductive region 26c and the light scattering region 26b in the present embodiment had a higher total transmittance than the Comparative Example for a wide range, except for the short wavelength region around the wavelength of 400 nm.

In this manner, by employing the layered structure of the light scattering region 26b and the conductive region 26c, it is possible to reduce the sheet resistance of the backside electrode layer 26 as a whole, and to improve a fill factor (FF) of the photovoltaic device 200. In addition, due to the light confinement effect caused by improvement of the haze rate and the reduction of the absorption loss of light caused by the improvement in the transmittance, the short-circuiting current density (Jsc) of the photovoltaic device 200 can also be improved.

The conductive region 26c formed under the film formation conditions shown in TABLE 4 has a higher density of the film than the light scattering region 26b. The film density can be measured by X-ray reflectometry analysis. Even when the film to be measured is layered with other films, the surface of the film to be measured can be exposed by etching, ion milling, or the like, and the density can be measured through the X-ray reflectometry analysis. Alternatively, electron energy-loss spectroscopy (EELS) may be applied to the cross section to measure the density of the film to be measured. Thus, it is possible to confirm that the backside electrode layer 26 includes the conductive region 26c by measuring the density of the film along the thickness direction of the backside electrode layer 26.

The conductive region 26c formed through sputtering includes larger amounts of zinc (Zn), gallium (Ga), silicon (Si), and copper (Cu) than the contact region 26a and the light scattering region 26b. Therefore, the existence of the conductive region 26c can be confirmed by measuring these elements through SIMS. Specifically, if a discontinuous point exists in the concentration changes of these elements along the thickness direction, it can be known that this point is the boundary between the light scattering region 26b and the conductive region 26c, and the backside electrode layer 26 has a layered structure including the conductive region 26c. In addition, the concentration distributions of other impurities such as aluminum (Al) also show a discontinuous point at the boundary between the conductive region 26c and the other layers.

As described above, in the photovoltaic device 200 according to the present embodiment, the backside electrode layer 26 is formed by layering the contact region 26a, the light scattering region 26b, and the conductive region 26c, so that a superior backside electrode layer 26 is obtained having a low contact resistance with the photovoltaic unit, a high electrical conductivity, a low light absorption, and a high light scattering effect, and the photovoltaic efficiency of the photovoltaic device 200 can be improved. In addition, a sufficient electrical conductivity can be achieved for the backside electrode layer 26 without forming a layer with a high conductivity such as a metal layer over the backside electrode layer 26. Because of this, the formation step of the metal layer can be omitted and effects of degradation or the like of the metal layer over time can also be avoided.

Alternatively, the order of layering of the backside electrode layer 26 may be changed to the contact region 26a, the conductive region 26c, and the light scattering region 26b from the side of the μc-Si unit 204.

Furthermore, the method of forming the contact region 26a, the light scattering region 26b, and the conductive region 26c is not limited to the above-described method. That is, any method may be employed which allows formation of the contact region 26a joined with the photovoltaic unit, the light scattering region 26b having a lower dopant concentration than the contact region 26a, and the conductive region 26c having a higher density than the light scattering region 26b. Moreover, in order to improve the light scattering effect, in the light scattering region 26b, an element different from the base material may be added, or a different substance may be mixed, to intentionally achieve a lower refractive index.

### First Alternative Embodiment

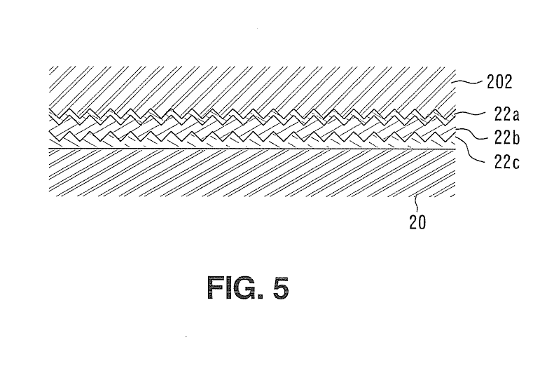

In the embodiment described above, only the backside electrode layer 26 is formed in the layered structure of 3 layers. Alternatively, it is also possible to employ a configuration as shown in FIG. 5 in which only the front-side electrode layer 22 has a layered structure of 3 layers. In this case, the layers are layered in the order of a conductive region 22c, a light scattering region 22b, and a contact region 22a from the side of the substrate 22, or in the order of the light scattering region 22b, the conductive region 22c, and the contact region 22a from the side of the substrate 20.

In this case, the contact region 22a, the light scattering region 22b, and the conductive region 22c can be formed in a manner similar to the contact region 26a, the light scattering region 26b, and the conductive region 26c in the above-described embodiment.

Here, when the contact region 22a is to be formed over the light scattering region 22b, it is preferable to continuously form the films of the light scattering region 22b and the contact region 22a as a transparent conductive film of a single layer. In particular, in order to achieve a structure where the crystallinity of the light scattering region 22b which forms the underlying layer is continued and the grain size of the contact region 22a becomes large, in the film formation, it is preferable to form the films such that the dopant concentration within the contact region 22a is gradually increased in the thickness direction near the boundary between the light scattering region 22b and the contact region 22a. More specifically, the contact region 22a is formed with, from the side closer to the light scattering region 22b, a transition region in which the dopant concentration continuously increases along the thickness direction, and a stable region which is positioned at a side closer to the photovoltaic unit than is the transition region and which has a smaller change of dopant concentration than the transition region. In particular, a thickness of the transition region is preferably set to greater than or equal to 1/20 and less than or equal to 1/10 of a total thickness of the contact region 22a and the light scattering region 22b.

As described, the front-side electrode layer 22 is formed by layering the contact region 22a, the light scattering region 22b, and the conductive region 22c, so that a superior front-side electrode layer 22 having a low contact resistance with the photovoltaic unit, a high electrical conductivity, a low light absorption, and a high light scattering effect can be achieved, and the photovoltaic efficiency of the photovoltaic device 200 can be improved.

### Second Alternative Embodiment

Alternatively, both the front-side electrode layer 22 and the backside electrode layer 26 may be formed in the layered structure of 3 layers. By employing a configuration where both of the front-side electrode layer 22 and the backside electrode layer 26 have the layered structure of 3 layers, the stress on both surfaces of the a-Si unit 202, the intermediate layer 24, and the μc-Si unit 204 which form the photovoltaic unit can be balanced, and the warping of the photovoltaic device 200 can be inhibited. With this configuration, problems such as the peeling off of the layered films do not occur, and the reliability of the photovoltaic device can be improved.

### Second Preferred Embodiment

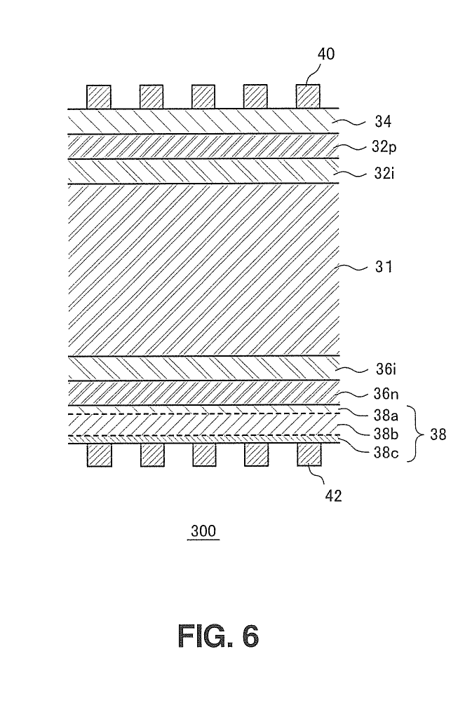

As shown in FIG. 6, a photovoltaic device 300 according to a second preferred embodiment of the present invention comprises a semiconductor substrate 31, an i-type amorphous layer 32i, a p-type amorphous layer 32p, a front-side electrode layer 34, an i-type amorphous layer 36i, an n-type amorphous layer 36n, a backside electrode 38, and collector electrodes 40 and 42.

The semiconductor substrate 31 is formed with a crystalline semiconductor material. The semiconductor substrate 31 may be a crystalline semiconductor substrate of an n-type conductive type or a p-type conductive type. For the semiconductor substrate 31, for example, a monocrystalline silicon substrate, a polycrystalline silicon substrate, a gallium arsenide substrate (GaAs), an indium phosphide substrate (InP), or the like may be applied. A texture structure may be provided on the surface of the semiconductor substrate 31. The front surface side of the semiconductor substrate 31 is set as a light receiving surface (a surface from which the light from the outside is primarily introduced).

The i-type amorphous layer 32i and the p-type amorphous layer 32p which are amorphous semiconductor layers are formed on the side of the light receiving surface of the semiconductor substrate 31. The i-type amorphous layer 32i is an amorphous intrinsic silicon semiconductor layer including hydrogen. A thickness of the i-type amorphous layer 32i is set to be greater than or equal to 1 nm and less than or equal to 25 nm, and is preferably set to be greater than or equal to 5 nm and less than or equal to 10 nm. The p-type amorphous layer 32p is a layer comprising an amorphous semiconductor film including a p-type conductive dopant. The p-type amorphous layer 32p is set to have a higher concentration of the p-type dopant in the film than the i-type amorphous layer 32i. A thickness of the p-type amorphous layer 32p is preferably set to be greater than or equal to 1 nm and less than or equal to 10 nm.

The i-type amorphous layer 36i and the n-type amorphous layer 36n which are amorphous semiconductor layers are formed on the side of the back surface of the semiconductor substrate 31. For the i-type amorphous layer 36i, an amorphous intrinsic silicon semiconductor layer including hydrogen is employed. Similar to the i-type amorphous layer 32i, a thickness of the i-type amorphous layer 36i is set to be greater than or equal to 1 nm and less than or equal to 25 nm, and preferably set to be greater than or equal to 5 nm and less than or equal to 10 nm. The n-type amorphous layer 36n is a layer comprising an amorphous semiconductor film including an n-type conductive dopant. The n-type amorphous layer 36n is set to have a higher concentration of the n-type dopant within the film than the i-type amorphous layer 36i. A thickness of the n-type amorphous layer 36n is preferably set to be greater than or equal to 1 nm and less than or equal to 10 nm.

The front-side electrode layer 34 and the backside electrode layer 38 are formed over the p-type amorphous layer 32p and the n-type amorphous layer 36n, respectively. The front-side electrode layer 34 may be formed in a manner similar to the front-side electrode layer 22 of the first preferred embodiment. The thickness of the front-side electrode layer 34 is suitably adjusted by the refractive index of the front-side electrode layer 34, and is preferably set to be greater than or equal to 70 nm and less than or equal to 100 nm.

The backside electrode layer 38 has a structure in which a contact region 38a, a light scattering region 38b, and a conductive region 38c are sequentially layered from the side of the semiconductor substrate 31. The contact region 38a, the light scattering region 38b, and the conductive region 38c may be formed in a manner similar to the contact region 26a, the light scattering region 26b, and the conductive region 26c in the first preferred embodiment.

The collector electrodes 40 and 42 are formed over the front-side electrode layers 34 and 38, respectively. The collector electrodes 40 and 42 are preferably formed in a comb-shaped finger electrode structure. The collector electrodes 40 and 42 may be formed through screen printing, coating, or the like. The collector electrodes 40 and 42 are formed, for example, by applying a silver paste or the like to a thickness of about a few tens of μm.

In the second preferred embodiment also, similar to the first preferred embodiment, the backside electrode layer 38 is formed in a structure in which the contact region 38a, the light scattering region 38b, and the conductive region 38c are layered, so that a high light scattering and a low resistance can be achieved, and the power generation efficiency of the photovoltaic device 300 can be improved.

In the photovoltaic device 300 in the second preferred embodiment, the i-type amorphous layer 32i, the p-type amorphous layer 32p, the front-side electrode layer 34, and the collector electrode 40 are provided on the side of the light receiving surface of the semiconductor substrate 31. Alternatively, a back contact-type photovoltaic device may be employed in which elements corresponding to these elements are provided on the side of the back surface (same side as the collector electrode 42 or the like) of the semiconductor substrate 31.

### Third Preferred Embodiment

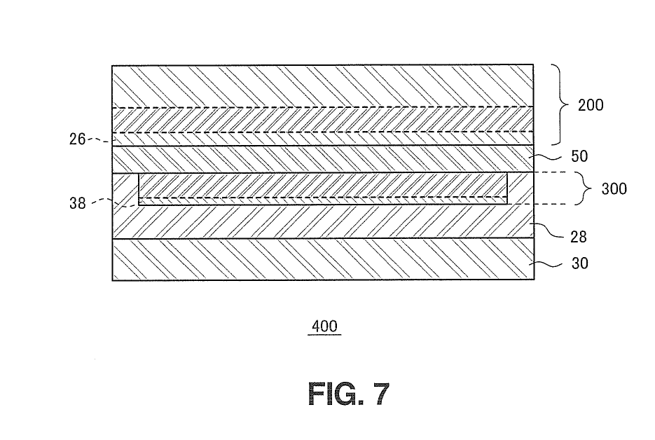

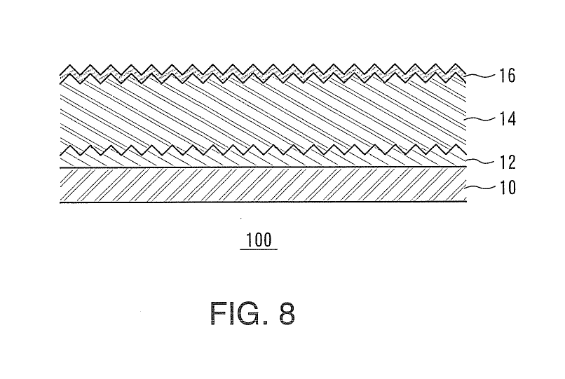

As shown in FIG. 7, a photovoltaic device 400 according to a third preferred embodiment of the present invention has a structure in which the photovoltaic device 200 according to the first preferred embodiment (in particular, the case of a single-type photovoltaic device formed with the a-Si unit) and the photovoltaic device 300 according to the second preferred embodiment are combined. Specifically, the photovoltaic device 300 is placed on the side of the back surface of the photovoltaic device 200 with a transparent insulating layer 50 therebetween, and the photovoltaic devices are sealed using the filler 28 and with the back sheet 30 (in particular, a transparent substrate such as a glass substrate and a plastic substrate). The photovoltaic device 200 and the photovoltaic device 300 are completely electrically isolated, and the generated powers are separately extracted.

By employing such a structure, a degree of freedom of current design for each photovoltaic device is improved compared to a case of a normal tandem-structured photovoltaic device, and the power generation capabilities of the photovoltaic devices can be maximized.

In this case, the backside electrode layer 26 comprises the contact region 26a, the light scattering region 26b, and the conductive region 26c, and is formed in a manner similar to the first preferred embodiment. Therefore, a high light scattering and a low resistance can be achieved, and the power generation efficiency of the photovoltaic device 200 can be improved.

The backside electrode layer 38 comprises the contact region 38a, the light scattering region 38b, and the conductive region 38c, and is formed in a manner similar to the second preferred embodiment. Therefore, a high light scattering and a low resistance can be achieved, and the power generation efficiency of the photovoltaic device 300 can be improved.

1. A photovoltaic device comprising:
a transparent substrate;
a front-side electrode layer formed over the substrate and comprising a transparent conductive film;
a photovoltaic unit formed over the front-side electrode layer; and
a backside electrode layer formed over the photovoltaic unit and comprising a transparent conductive film, wherein
the backside electrode layer has a structure in which
a first contact region joined with the photovoltaic unit,
a first light scattering region having a lower dopant concentration than the first contact region, and
a first conductive region having a higher density than the first light scattering region, are layered.

2. The photovoltaic device according to claim 1, wherein
the front-side electrode layer has a structure in which
a second contact region joined with the photovoltaic unit,
a second light scattering region having a lower dopant concentration than the second contact region, and
a second conductive region having a higher density than the second light scattering region, are layered.

3. The photovoltaic device according to claim 1, wherein
no metal layer is provided over the backside electrode layer.

4. A photovoltaic device comprising:
a crystalline semiconductor substrate;
a first amorphous semiconductor layer which is intrinsic and which is formed over a surface opposite to a light receiving surface of the semiconductor substrate;
a second amorphous semiconductor layer of a first conductive type formed over the first amorphous semiconductor layer; and
a backside electrode layer formed over the second amorphous semiconductor layer and comprising a transparent conductive film, wherein
the backside electrode layer has a structure in which
a first contact region joined with the second amorphous semiconductor layer,
a first light scattering region having a lower dopant concentration than the first contact region, and
a first conductive region having a higher density than the first light scattering region, are layered.

5. The photovoltaic device according to claim 4, further comprising:
a third amorphous semiconductor layer which is intrinsic and which is formed over the light receiving surface of the crystalline semiconductor substrate;
a fourth amorphous semiconductor layer of a second conductive type formed over the third amorphous semiconductor layer; and
a backside electrode layer formed over the fourth amorphous semiconductor layer and comprising a transparent conductive film.

6. A photovoltaic device having a structure in which a first photovoltaic device and a second photovoltaic device are layered,
wherein the first photovoltaic device comprises:
a transparent substrate;
a front-side electrode layer formed over the substrate and comprising a transparent conductive film;
a photovoltaic unit formed over the front-side electrode layer; and
a backside electrode layer formed over the photovoltaic unit and comprising a transparent conductive film, wherein
the backside electrode layer has a structure in which
a first contact region joined with the photovoltaic unit,
a first light scattering region having a lower dopant concentration than the first contact region, and
a first conductive region having a higher density than the first light scattering region, are layered, and
wherein the second photovoltaic device comprises:
a crystalline semiconductor substrate;
a first amorphous semiconductor layer which is intrinsic and which is formed over a surface opposite to a light receiving surface of the semiconductor substrate;
a second amorphous semiconductor layer of a first conductive type formed over the first amorphous semiconductor layer; and
another backside electrode layer formed over the second amorphous semiconductor layer and comprising another transparent conductive film, wherein
the another backside electrode layer has another structure in which
another first contact region joined with the second amorphous semiconductor layer,
another first light scattering region having a lower dopant concentration than the another first contact region, and
another first conductive region having a higher density than the another first light scattering region, are layered.

7. The photovoltaic device according to claim 2, wherein
no metal layer is provided over the backside electrode layer.
